(19) United States
(12) Patent Application Publication
(10) Pub. No.: US 2002/0038896 A1
(43) Pub. Date: Apr. 4, 2002

(54) Semiconductor device including a depletion type lateral mosfet and method of forming the same

(75) Inventor: Takao Arai, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/963,533

(22) Filed: Sep. 27, 2001

(30) Foreign Application Priority Data
Sep. 29, 2000 (JP) 2000-297892

(51) Int. Cl. H01L 29/94; H01L 31/113; H01L 31/119

(52) U.S. Cl. 257/368

(57) ABSTRACT

The present invention provides a channel region of a depletion type lateral field effect transistor. The channel region of a first conductivity type is selectively provided in a semiconductor region of a second conductivity type, and the channel region underlies a gate insulating film, wherein an interface of the channel region to the gate insulating film lies at a lower level than an upper surface of the semiconductor region.

### BACKGROUND OF THE INVENTION

1. Field of the Invention

The present invention relates to a semiconductor device and a method of forming the same, and more particularly to a semiconductor device which includes both a vertical MOS field effect transistor in a semiconductor substrate and a depletion type lateral MOS field effect transistor in a well region in the semiconductor substrate.

2. Description of the Related Art

Japanese patent No. 277155 and Japanese laid-open patent publication No. 10-233506 disclose conventional semiconductor devices, each of which includes both a vertical MOS field effect transistor in a semiconductor substrate and a depletion type lateral MOS field effect transistor in a well region in the semiconductor substrate. FIGS. 1A through 1K are fragmentary cross sectional elevation views illustrative of conventional semiconductor devices in sequential steps involved in a conventional method for forming the same.

With reference to FIG. 1A, an n⁻-type epitaxial layer 23 with a low impurity concentration is formed over an n+-type semiconductor substrate 22 with a high impurity concentration. An oxide film 24 is formed over the n⁻-type epitaxial layer 23. A resist film is applied on the oxide film 24. The resist film is then patterned by a lithography process to form a resist pattern. The resist pattern is used as a mask for selectively etching the oxide film 24, so that a part of the upper surface of the n⁻-type epitaxial layer 23 is exposed through an opening of the oxide film 24. The used resist film is then removed.

With reference to FIG. 1B, the oxide film 24 with the opening is used as a mask for selective ion-implantation of boron as a p-type impurity into a selected region of the n⁻-type epitaxial layer 23. A heat treatment is then carried out for activation of the implanted impurity in the selected region of the n⁻-type epitaxial layer 23, thereby to selectively form a p-well region 25 in the n⁻-type epitaxial layer 23.

With reference to FIG. 1C, the oxide film 24 is completely removed. A selective wet oxidation is carried out using masks to selectively form field oxide films 26 on the upper surface of the p-well region 25 and on the upper surface of the n⁻-type epitaxial layer 23.

With reference to FIG. 1D, a resist film is entirely applied over the field oxide films 26, the upper surface of the p-well region 25 and the upper surface of the n⁻-type epitaxial layer 23. The resist film is then patterned by a lithography technique to form a resist pattern 27 having an opening which is positioned over a part of the p-well region 25. The resist pattern 27 is used as a mask for selective ion-implantation of arsenic or phosphorous as an n-type impurity into a selected region in the p-well region 25, thereby forming an n-type region 28 which serves as a channel region of a depletion type lateral MOS field effect transistor. This n-type impurity is for adjusting a threshold voltage of the depletion type lateral MOS field effect transistor.

With reference to FIG. 1E, the used resist pattern 27 is completely removed. The upper surfaces of the p-well region 25 and the n-type epitaxial layer 23 are subjected to an oxidation to form gate oxide films 29a and 29b over the upper surface of the p-well region 25 as well as form a gate oxide film 29c over the upper surface of the n⁻-type epitaxial layer 23. A polysilicon layer doped with an n-type impurity is entirely formed over the field oxide films 26 and the gate oxide films 29a, 29b and 29c. The n-doped polysilicon layer is then patterned by a lithography technique and a subsequent selective etching process to form gate electrodes 30a, 30b and 30c. The gate electrode 30a is positioned over the gate oxide film 29a. This gate electrode 30a is a gate electrode for the depletion type lateral MOS field effect transistor in the p-well region 25. The gate electrode 30b is positioned over the gate oxide film 29b. This gate electrode 30b is a gate electrode for the enhancement type lateral MOS field effect transistor in the p-well region 25. The gate electrodes 30c are positioned over the gate oxide film 29c. This gate electrodes 30c are gate electrodes for the vertical MOS field effect transistors in the n⁻-type epitaxial layer 23.

With reference to FIG. 1F, a resist film is entirely applied over the gate electrodes 30a, 30b and 30c and the gate oxide films 29a, 29b and 29c as well as over the field oxide films 26. The resist film is then patterned by a lithography technique to form a resist pattern 31 which covers the p-well region 25.

With reference to FIG. 1G, the resist pattern 31 and the gate electrodes 30c are used as masks for selective ion-implantation of boron as a p-type impurity into the n⁻-type epitaxial layer 23. The used resist pattern 31 is removed. A heat treatment is then carried out for activation of the implanted impurity, thereby selectively forming p-type regions 32 in the n⁻-type epitaxial layer 23, wherein the p-type regions 32 are positioned under gaps between the gate electrodes 30c. The p-type regions 32 serve as body regions of the vertical MOS field effect transistors. Another resist film is further applied entirely over the gate electrodes 30a, 30b and 30c, and the gate oxide films 29a, 29b and 29c as well as over the field oxide films 26. The resist film is then patterned by a lithography technique to form a resist pattern 33 which has openings positioned between the gate electrodes 30c and over the p-type regions 32, so that parts of the upper surfaces of the p-type regions 32 are exposed through the openings of the resist pattern 33.

With reference to FIG. 1H, the resist pattern 33 is used as a mask for selective ion-implantation of boron as a p-type impurity into the p-type regions 32 at a high impurity concentration. The resist pattern 33 is completely removed. A heat treatment is then carried out for activation of the implanted impurity to selectively form p+-type regions 34 in the p-type regions 32. The p+-type regions 34 are higher in impurity concentration than the p-type regions 32. The p+-type regions 34 serve to suppress effective operations of parasitic bipolar transistors to the vertical MOS field effect transistors. Still another resist film is entirely applied over the gate electrodes 30a, 30b and 30c, and the gate electrodes 29a, 29b and 29c as well as over the field oxide films 26. The resist film is then patterned by a lithography technique to form resist patterns 35 which are positioned over the p+-type regions 34.

With reference to FIG. 11, the resist patterns 35, the gate electrodes 30a, 30b and 30c and the field oxide films 26 are used as masks for selective ion-implantation of arsenic as an n-type impurity into selected regions in the p-well region 25 and in the p+-type regions 34 at a high impurity concentration. The used resist patterns 35 are completely removed. A heat treatment is then carried out for activation of the implanted impurity, thereby to selectively form n+-type regions 36a, 36b, 36c and 36d in the p-well region 25, and n+-type regions 36e in the p+-type regions 34. The n+type regions 36a and 36b serve as source and drain regions of the depletion type lateral MOS field effect transistor in the p-well region 25. The n+-type regions 36c and 36d serve as source and drain regions of the enhancement type lateral MOS field effect transistor in the p-well region 25. The n+-type regions 36e serve as source regions of the vertical MOS field effect transistors in the n⁻-type epitaxial layer 23. An inter-layer insulator 37 is entirely formed over the gate electrodes 30a, 30b and 30c, and the gate electrodes 29a, 29b and 29c as well as over the field oxide films 26. Yet another resist film is entirely applied over the inter-layer insulator 37. The resist film is then patterned by a lithography technique to form a resist pattern 28 with openings which are positioned over contact regions of the inter-layer insulator 37.

With reference to FIG. 1J, the resist pattern 28 is used as a mask for selectively etching the inter-layer insulator 37 and the gate oxide films 29a, 29b and 29c to form contact holes in the inter-layer insulator 37. The contact holes are positioned over the n+-type regions 36a, 36b, 36c and 36d, as well as over the p+-type regions 34 and the n+-type regions 36e, whereby parts of the n+-type regions 36a, 36b, 36c and 36d as well as the p+-type regions 34 and parts of the n+-type regions 36e are exposed through the contact holes in the inter-layer insulator 37. The used resist pattern 38 is completely removed. An aluminum layer 39 is entirely formed over the inter-layer insulator 37 and within the contact holes, so that the aluminum layer 39 is in contact with the parts of the n+-type regions 36a, 36b, 36c and 36d as well as the p+-type regions 34 and the parts of the n+type regions 36e. A resist film is further applied entirely over the aluminum layer 39. The resist film is then patterned by a lithography technique to form a resist pattern 40.

With reference to FIG. 1K, the resist pattern 40 is used as a mask for selectively etching the aluminum layer 39 to form aluminum electrodes 39a, 39b, 39c, 39d, and 39e. The aluminum electrodes 39a and 39b are in contact with the source and drain regions 36a and 36b of the depletion type lateral MOS field effect transistor in the p-well region 25, so that the aluminum electrodes 39a and 39b serve as source and drain electrodes of the depletion type lateral MOS field effect transistor. The aluminum electrodes 39c and 39d are in contact with the source and drain regions 36c and 36d of the enhancement type lateral MOS field effect transistor in the p-well region 25, so that the aluminum electrodes 39c and 39d serve as source and drain electrodes of the enhancement type lateral MOS field effect transistor. The aluminum electrode 39c is in contact with the p+-type regions 34 and the parts of the n+-type regions 36e in the p-type regions 32, so that the aluminum electrode 39c serves as a source electrode of the vertical MOS field effect transistor. The used resist pattern 40 is completely removed. A bottom electrode 41 is formed on a bottom surface of the semiconductor substrate 22.

The above conventional semiconductor device has a circuit configuration which includes the n-channel MOS field effect transistors and the p-channel MOS field effect transistors only. The above conventional semiconductor device may be fabricated by small number of additional processes in additional to the processes for the vertical MOS field effect transistors. This allows a manufacturing cost reduction. The above conventional semiconductor device is, however, disadvantageous in a large variation in threshold voltage of the depletion type lateral MOS field effect transistor. This makes it difficult to design the circuit. If the variation in threshold voltage exceeds an acceptable range, then this means the semiconductor device to be defect, whereby the yield is dropped.

The following description will focus on the reason why the variation in the threshold voltage of the depletion type lateral MOS field effect transistor is large. Assuming that the enhancement type lateral MOS field effect transistor has a threshold voltage of 1V and the depletion type lateral MOS field effect transistor has a threshold voltage of −1V, a surface impurity concentration of the p-well region 25 is ranged from about 1E16 cm⁻³ to 1E17 cm⁻³, and another surface concentration of the n-type region 28 is ranged from about 1E13 cm⁻³ to 1E15 cm⁻³, provided that the surface concentration of the n-type region 28 depends on a depth of a p-n junction between the n-type regions 28 and the p-well region 25.

Assuming hereby that the surface impurity concentration of the p-well region 25 is 1E16 cm⁻³, and the surface concentration of the n-type region 28 is 1E13 cm⁻³, a boron concentration of the surface region of the p-well region 25 is 1E16 cm⁻³, and an arsenic or phosphorus concentration of the surface region of the n-type region 28 is 1.001E16 cm⁻³. Namely, the impurity concentration of 1E13 cm⁻³ of the n-type region 28 corresponds to a subtraction of the boron concentration of 1E16 cm⁻³ from the arsenic or phosphorus concentration of 1.001E16 cm⁻³. If the arsenic or phosphorus concentration varies by only 1% from 1E16 cm⁻³ to 1.002E16 cm⁻³, then the impurity concentration of the n-type region 28 is 2E13 cm⁻³ because of 1.002E16 cm⁻³⁻¹E16 cm^{-3=0.002}E16 cm⁻³⁼²E13 cm⁻³. The variation in surface impurity concentration of the n-type region 28 is 100% of the target surface impurity concentration of 1E13 cm⁻³.

The threshold voltage is almost proportional to a logarithm of the impurity concentration. For this reason, the variation in threshold voltage of the depletion type lateral MOS field effect transistor is much larger than the variation in threshold voltage of the enhancement type lateral MOS field effect transistor.

If the p-n junction between the n-type region 28 and the p-well region 25 is so shallow that a depletion layer from the p-n junction reaches the gate oxide film 29a and no further extension of the depletion layer is possible, then a neutralization of charges at the p-n junction is established not only by the depletion layer but also injection of positive charges into the gate electrode 30a upon an additional voltage application to the gate electrode 30a. This additional voltage application to the gate electrode 30a increases the threshold voltage of the depletion type lateral MOS field effect transistor. If the threshold voltage of the depletion type lateral MOS field effect transistor is fixed, the decrease in depth of the p-n junction results in the increase in impurity concentration of the n-type region 28. The increase in impurity concentration of the n-type region 28 reduces the variation in threshold voltage of the depletion type lateral MOS field effect transistor. Namely, in order to reduce the variation in threshold voltage of the depletion type lateral MOS field effect transistor, it is effective to decrease the depth of the p-n junction between the n-type region 28 and the p-well region 25.

In accordance with the above conventional fabrication method, after the n-type region 28 has been formed, the heat treatments are carried out for forming the p-type regions 32 and the p+-type regions 34. Those heat treatments are carried out at high temperature, for example, 1140° C. for a relatively long time, for example, about several tends minutes. Those heat treatments cause an undesirable diffusion of the n-type region 28, so that the p-n junction depth is also made deep. Namely, the heat treatments make it difficult to form a desirable shallow p-n junction. This means that the heat treatments make it difficult to suppress variation in threshold voltage of the depletion type lateral MOS field effect transistor.

In the above circumstances, the development of a novel semiconductor device and method of forming the same free from the above problems is desirable.

### SUMMARY OF THE INVENTION

Accordingly, it is an object of the present invention to provide a novel semiconductor device including a depletion type lateral MOS field effect transistor in a well region free from the above problems.

It is a further object of the present invention to provide a novel semiconductor device including a depletion type lateral MOS field effect transistor in a well region, wherein the transistor has a small variation in threshold voltage.

It is a still further object of the present invention to provide a novel method of forming a semiconductor device including a depletion type lateral MOS field effect transistor in a well region free from the above problems.

It is yet a further object of the present invention to provide a novel method of forming a semiconductor device including a depletion type lateral MOS field effect transistor in a well region, wherein the transistor has a small variation in threshold voltage.

The present invention provides a channel region of a depletion type lateral field effect transistor. The channel region of a first conductivity type is selectively provided in a semiconductor region of a second conductivity type, and the channel region underlies a gate insulating film, wherein an interface of the channel region to the gate insulating film lies at a lower level than an upper surface of the semiconductor region.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIGS. 1A through 1K are fragmentary cross sectional elevation views illustrative of conventional semiconductor devices in sequential steps involved in a conventional method for forming the same.

FIGS. 2A through 2L are fragmentary cross sectional elevation views illustrative of novel semiconductor devices in sequential steps involved in a novel method for forming the same in a preferred embodiment in accordance with the present invention.

FIG. 3 is a diagram illustrative of variations in threshold voltage of the novel and conventional depletion type lateral MOS field effect transistors versus surface impurity concentration of channel region thereof in both the preferred embodiment of the present invention and the prior art.

FIG. 4 is a diagram illustrative of threshold voltage values of the novel and conventional depletion type lateral MOS field effect transistors versus in-plane variations of the threshold voltage over wafer in both the preferred embodiment of the present invention and the prior art.

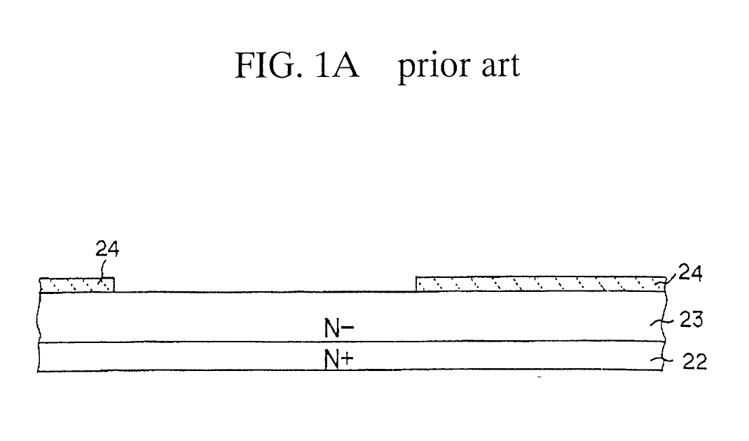

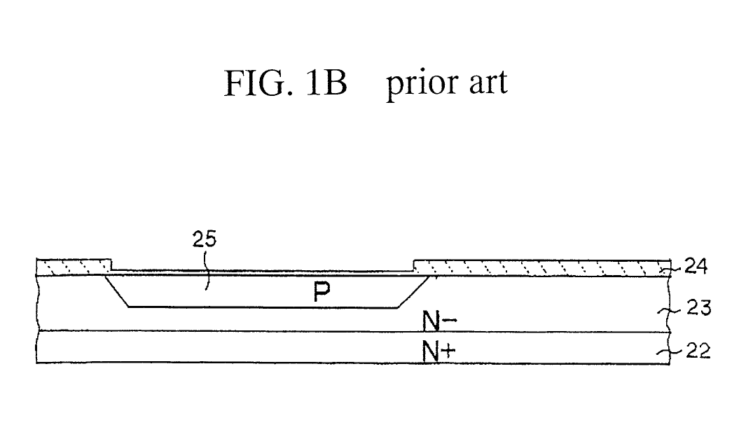

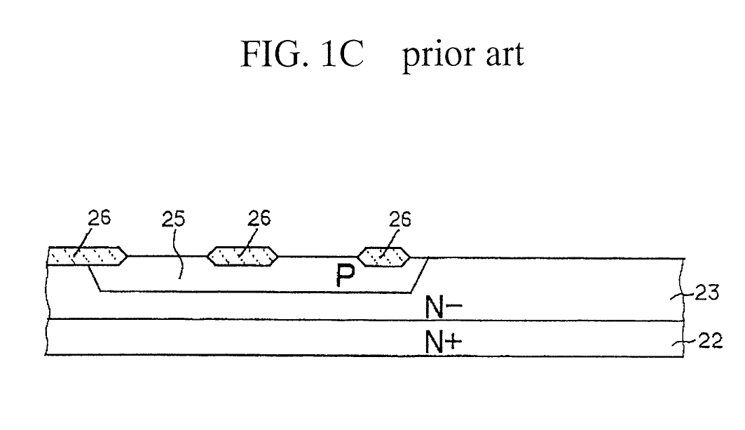

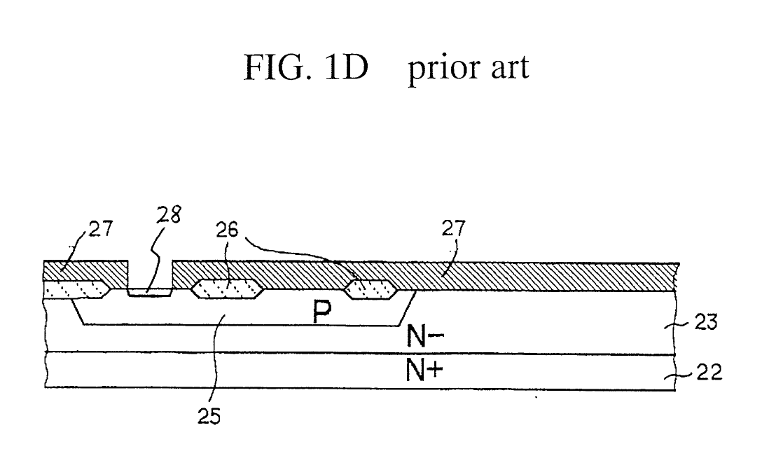

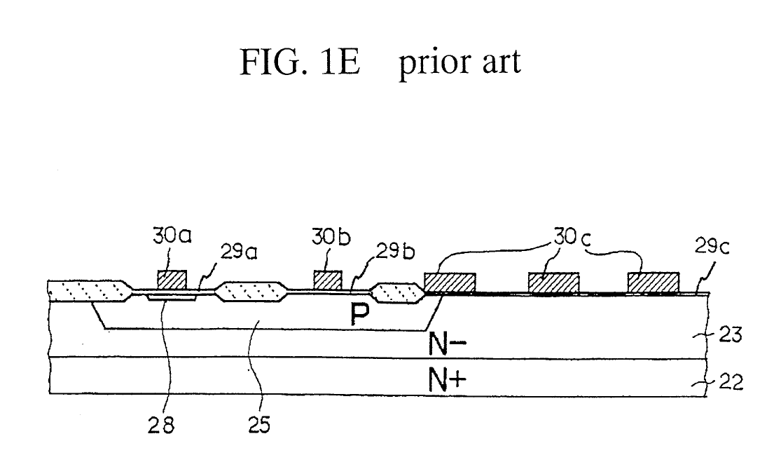

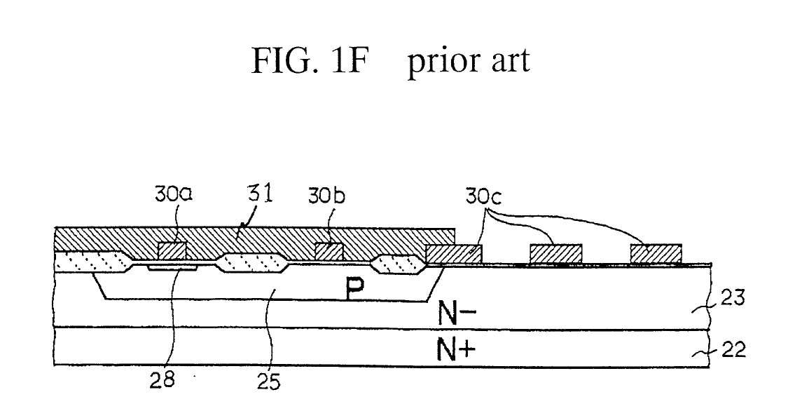

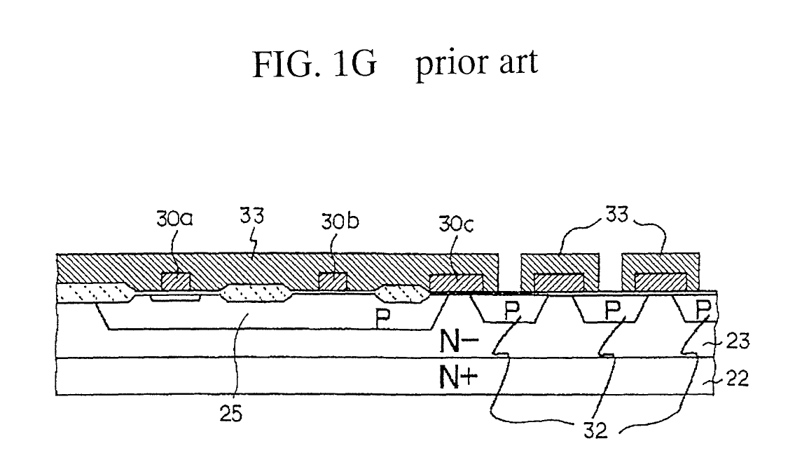

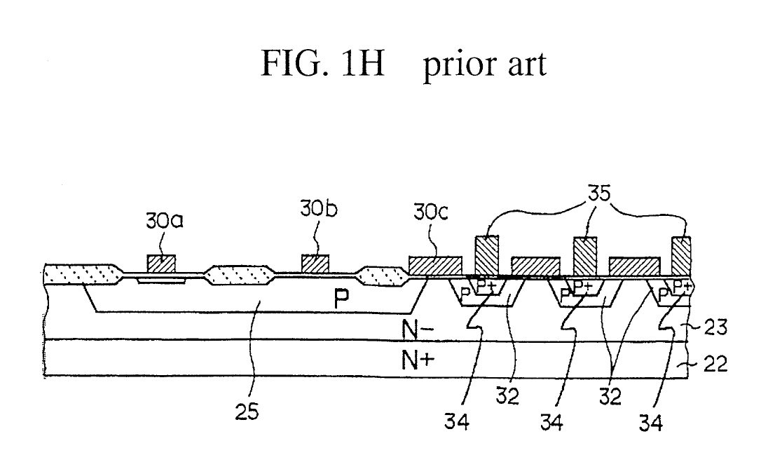

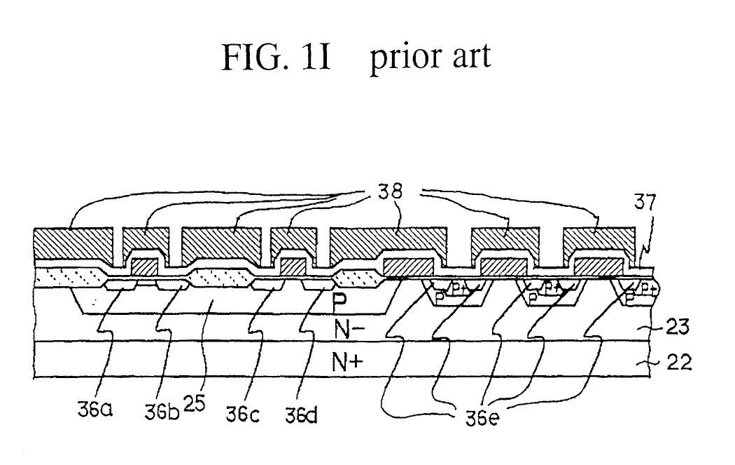

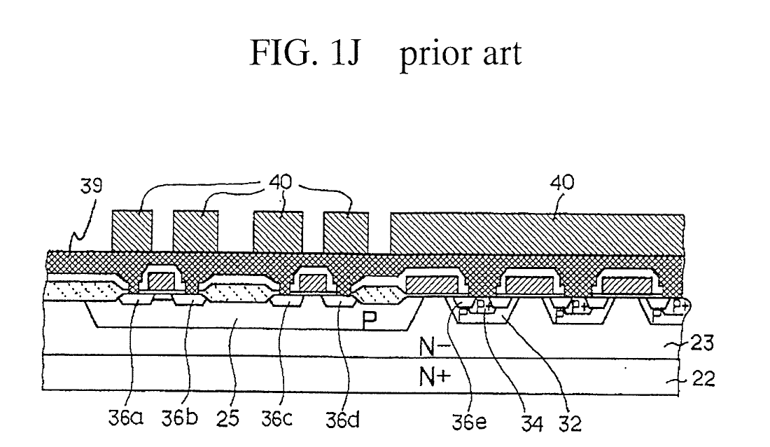

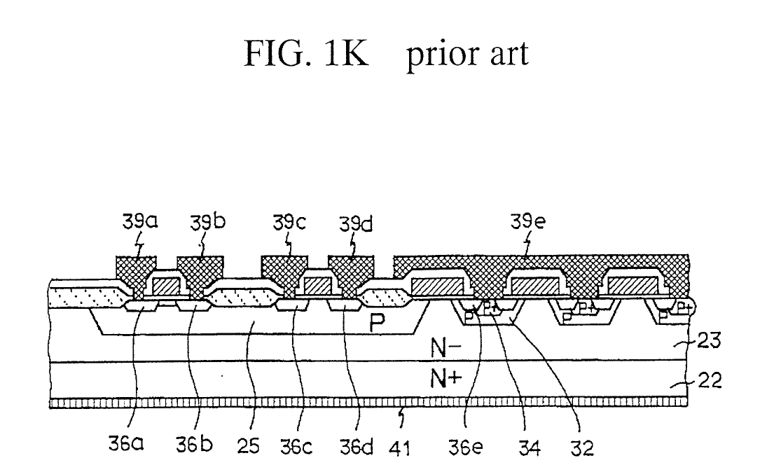

### DETAILED DESCRIPTION OF THE PREFERRED EMBODIMENTS

A first aspect of the present invention is a channel region of a depletion type lateral field effect transistor. The channel region of a first conductivity type is selectively provided in a semiconductor region of a second conductivity type, and the channel region underlies a gate insulating film, wherein an interface of the channel region to the gate insulating film lies at a lower level than an upper surface of the semiconductor region.

The semiconductor region may comprise a well region selectively provided in a semiconductor substrate.

The channel region may comprise a diffusion layer doped with an impurity of the first conductivity type which is for adjustment to a threshold voltage of the depletion type lateral field effect transistor.

A second aspect of the present invention is a well region for a depletion type lateral field effect transistor. The well region of a second conductivity type is selectively provided in a semiconductor substrate. The well region has an upper surface and including an impurity diffused region which is selectively provided in the well region. The impurity diffused region is doped with an impurity of a first conductivity type which is for adjustment to a threshold voltage of the depletion type lateral field effect transistor, wherein the upper surface of the impurity diffused region lies at a lower level than the upper surface of the well region.

The upper surface of the impurity diffused region is bounded with a gate insulating film.

The impurity diffused region forms a channel layer of the depletion type lateral field effect transistor.

A third aspect of the present invention is a semiconductor wafer comprising: a semiconductor substrate of a first conductivity type; an epitaxial layer of the first conductivity type overlying the semiconductor substrate; a well region of a second conductivity type selectively provided in the epitaxial layer; and an impurity diffused channel region being selectively provided in the well region, and the impurity diffused channel region being doped with an impurity of the first conductivity type which is for adjustment to a threshold voltage of a depletion type lateral field effect transistor, wherein the upper surface of the impurity diffused channel region lies at a lower level than the upper surface of the well region.

The upper surface of the impurity diffused region is bounded with a gate insulating film.

A fourth aspect of the present invention is a depletion type lateral MOS field effect transistor comprising: a channel region of a first conductivity type being selectively provided in a semiconductor region of a second conductivity type; source and drain regions of the first conductivity type being selectively provided in the semiconductor region, the channel region being interposed between the source and drain regions; a gate insulating film extending over the channel region; and a gate electrode provided on the gate insulating film, wherein an interface of the channel region to the gate insulating film lies at a lower level than an upper surface of the semiconductor region.

The semiconductor region may comprise a well region selectively provided in an epitaxial layer of the first conductivity type, and the epitaxial layer overlying a semiconductor substrate of the first conductivity type.

The channel region may comprise a diffusion layer doped with an impurity of the first conductivity type which is for adjustment to a threshold voltage of the depletion type lateral field effect transistor.

A fifth aspect of the present invention is a semiconductor wafer including: an impurity diffused region of a first conductivity type being selectively provided in a semiconductor region of a second conductivity type; and an oxide film overlying the impurity diffused region, wherein an interface of the impurity diffused region to the oxide film lies at a lower level than an upper surface of the semiconductor wafer.

The semiconductor region may comprise a well region selectively provided in a semiconductor substrate.

The channel region may comprise a diffusion layer doped with an impurity of the first conductivity type which is for adjustment to a threshold voltage of a depletion type lateral field effect transistor.

The oxide film may have a thickness of at least 5000 angstroms.

A sixth aspect of the present invention is a method of forming a channel region of a depletion type lateral field effect transistor, comprising the steps of: selectively forming a channel region of a first conductivity type in a semiconductor region of a second conductivity type; subjecting an upper region of the channel region to a selective oxidation to form an oxide film which overlies the channel region, wherein an interface of the impurity diffused region to the oxide film lies at a lower level than an upper surface of the semiconductor wafer.

The oxide film may have a thickness of at least 5000 angstroms.

The semiconductor region may comprise a well region selectively formed in an epitaxial layer over a semiconductor substrate.

The channel region may comprise a diffusion layer doped with an impurity of the first conductivity type which is for adjustment to a threshold voltage of a depletion type lateral field effect transistor.

The oxidation may be a wet oxidation.

The oxide film overlying the channel region may be formed at the same time of forming at least a field oxide film.

A seventh aspect of the present invention is a method of forming a channel region of a depletion type lateral field effect transistor, comprising the steps of: selectively introducing a first impurity of a second conductivity type at a first impurity concentration into a first selected region of a semiconductor region of a first conductivity type; selectively introducing a second impurity of the first conductivity type at a second impurity concentration into a second selected region in the first selected region, the second impurity concentration being higher than the first impurity concentration; carrying out a heat treatment for activating the first and second impurities to form a well region on the first selected region and a channel region on the second selected region concurrently; and subjecting an upper region of the channel region to a selective oxidation to form an oxide film which overlies the channel region, so that an interface of the impurity diffused region to the oxide film lies at a lower level than an upper surface of the semiconductor wafer.

The oxide film may have a thickness of at least 5000 angstroms.

The semiconductor region may comprise a well region selectively formed in an epitaxial layer over a semiconductor substrate.

The channel region may comprise a diffusion layer doped with an impurity of the first conductivity type which is for adjustment to a threshold voltage of a depletion type lateral field effect transistor.

The oxidation may be a wet oxidation.

The oxide film overlying the channel region may be formed at the same time of forming at least a field oxide film.

First Embodiment:

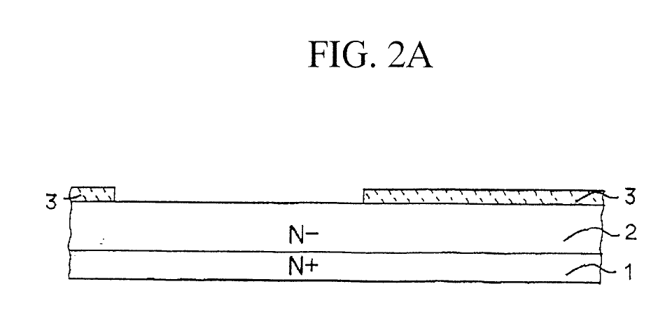

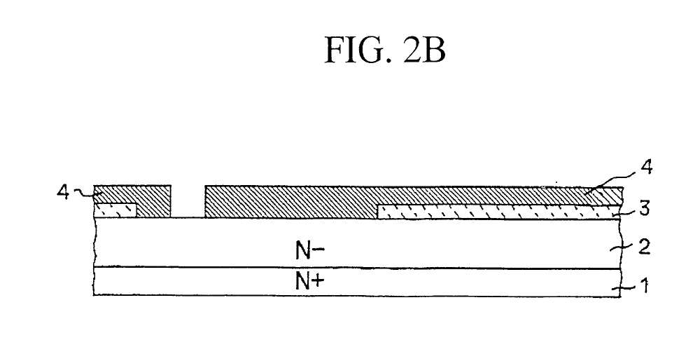

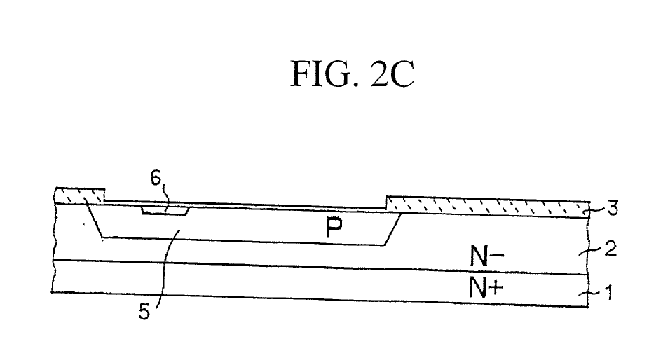

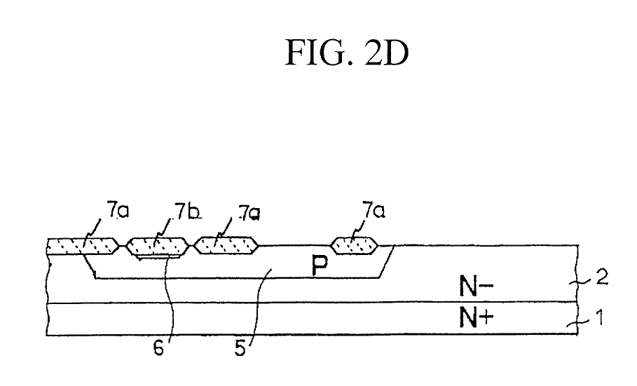

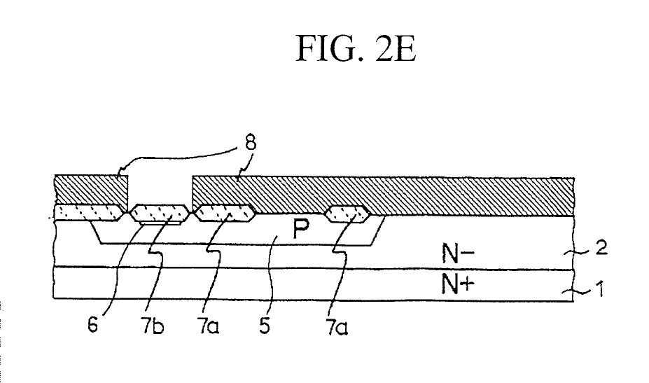

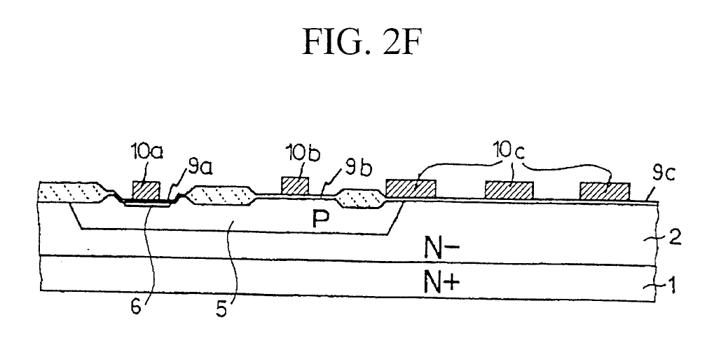

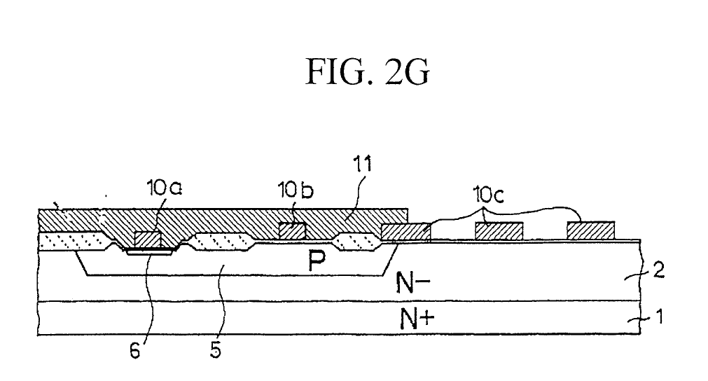

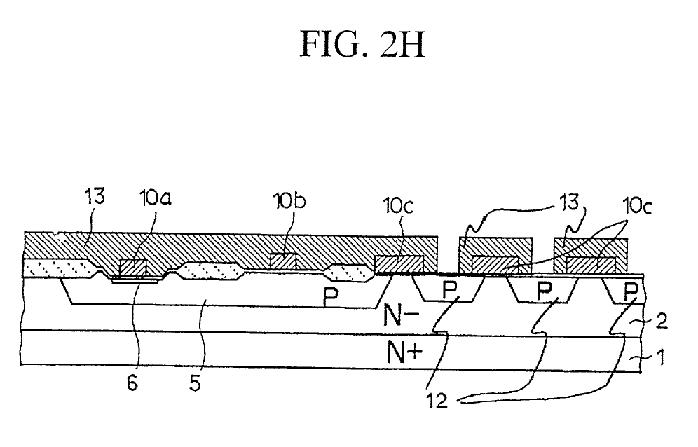

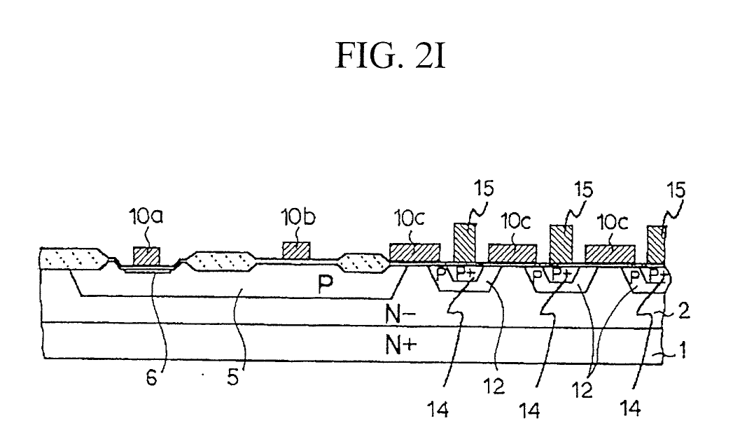

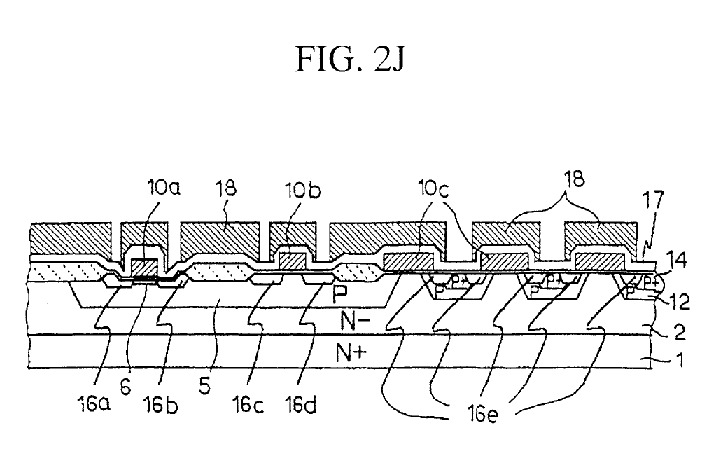

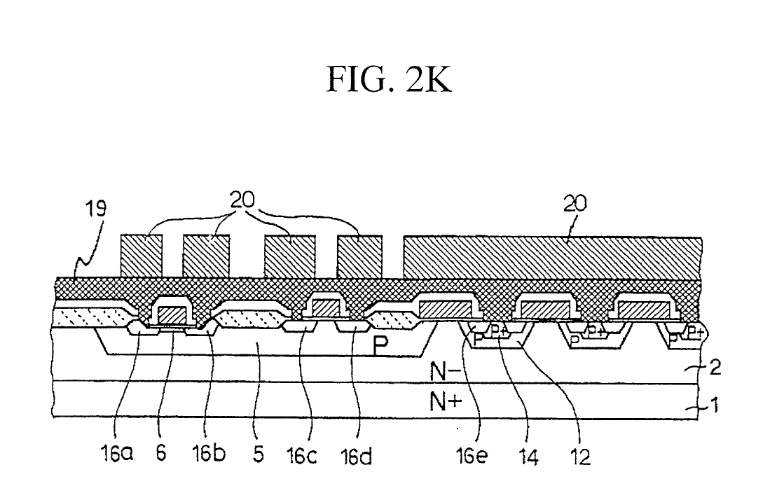

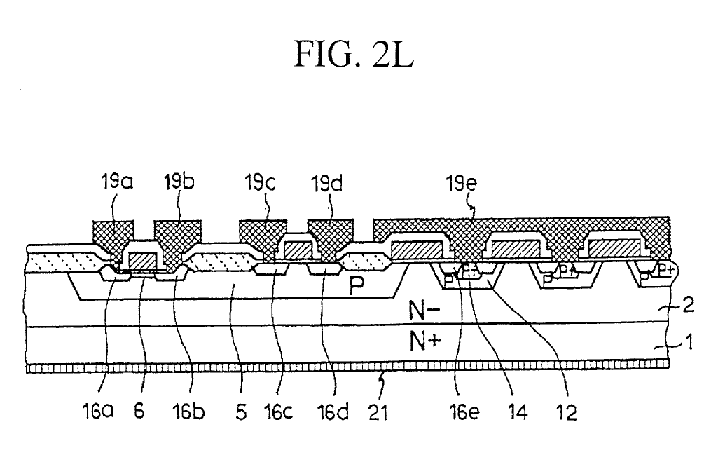

A first embodiment according to the present invention will be described in detail with reference to the drawings. FIGS. 2A through 2L are fragmentary cross sectional elevation views illustrative of novel semiconductor devices in sequential steps involved in a novel method for forming the same in a preferred embodiment in accordance with the present invention.

With reference to FIG. 2A, an n⁻-type epitaxial layer 2 with a low impurity concentration is formed over an n+-type semiconductor substrate 1 with a high impurity concentration. An oxide film 3 is formed over the n⁻-type epitaxial layer 2. A resist film is applied on the oxide film 3. The resist film is then patterned by a lithography process to form a resist pattern. The resist pattern is used as a mask for selectively etching the oxide film 3, so that a part of the upper surface of the n⁻-type epitaxial layer 2 is exposed through an opening of the oxide film 3. The used resist film is then removed. The oxide film 3 is used as a mask for selective ion-implantation of boron as a p-type impurity into the n⁻-type epitaxial layer 2 at an impurity concentration of 1.5E13 cm⁻².

With reference to FIG. 2B, a resist film is entirely applied over the n⁻-type epitaxial layer 2 and the oxide film 3. The resist film is then patterned by a lithography technique to form a resist pattern 4 with an opening which is positioned over a part of an upper surface of the n⁻-type epitaxial layer 2. The resist pattern 4 is used as a mask for selective ion-implantation of arsenic as an n-type impurity into a selected region of the p-type impurity doped region of the n⁻-type epitaxial layer 2 at an impurity concentration of 6.012 cm⁻² for adjusting a threshold voltage of a depletion type lateral MOS field effect transistor.

With reference to FIG. 2C, the used resist pattern 4 is removed. A heat is carried out at a temperature of 1140° C. for 240 minutes for activating the implanted boron and arsenic, thereby forming both a p-well region 5 in the n⁻-type epitaxial layer 2 and an n-type region 6 in the p-well region 5 concurrently. The n-type region 6 is defined by the opening of the resist pattern 4. The p-well region 5 is defined by the opening of the oxide film 3.

With reference to FIG. 2D, the oxide film 3 is completely removed. A selective wet oxidation is carried out using masks at 1000° C. to selectively form field oxide films 7a on the upper surface of the p-well region 5, and form an additional oxide film 7b on the n-type region 6. The field oxide films 7a and the additional oxide film 7b have a thickness of about 1 micrometers. The field oxide films 7a are provided for suppressing the operation of the parasitic MOS field effect transistor. The additional oxide film 7b covers the upper surface of the n-type region 6. The additional oxide film 7b is formed by an oxidation of an upper region of the n-type region 6, whereby an interface of the n-type region 6 to the additional oxide film 7b lies at a lower level than an upper surface of the p-well region 5 or the upper surface of the original n-type region 6. In the oxidation process, a segregation and a shift of the interface of the n-type region 6 to the additional oxide film 7b in a downward direction reduce an effective depth of the p-n junction of the n-type region 6 to the p-well region 5 from the interface between the n-type region 6 and the additional oxide film 7b. Namely, the oxidation of the upper region of the original n-type region 6 for forming the additional oxide film 7b makes the p-n junction more shallow. The n-type region 6 includes a low concentration of boron as the p-type impurity and a high concentration of arsenic as the n-type impurity. The segregation in the oxidation of the upper region of the original n-type region 6 for forming the additional oxide film 7b reduces the concentration of boron as the p-type impurity in the n-type region 6. The reduced concentration of boron as the p-type impurity in the n-type region 6 suppresses the p-n junction from being deeper in a later heat treatment. The additional oxide film 7b may preferably have a thickness of at least 5000 angstroms.

With reference to FIG. 2E, a resist film is entirely applied over the field oxide films 7a and the additional oxide film 7b, the upper surface of the p-well region 5 and the upper surface of the n⁻-type epitaxial layer 2. The resist film is then patterned by a lithography technique to form a resist pattern 8 having an opening which is positioned over the additional oxide film 7b. The resist pattern 8 is used as a mask for removing the additional oxide film 7b.

With reference to FIG. 2F, the resist pattern 8 is removed. The upper surfaces of the p-well region 5 and the n⁻-type epitaxial layer 2 as well as an upper surface of the n-type region 6 are subjected to an oxidation to form a gate oxide film 9a over the n-type region 6 and another gate oxide film 9b over the upper surface of the p-well region 5 as well as form a gate oxide film 9c over the upper surface of the n⁻-type epitaxial layer 2. The gate oxide films 9a, 9b and 9c have a thickness of 300 angstroms. A polysilicon layer doped with an n-type impurity is entirely formed over the field oxide films 7a and the gate oxide films 9a, 9b and 9c. The n-doped polysilicon layer is then patterned by a lithography technique and a subsequent selective etching process to form gate electrodes 10a, 10b and 10c. The gate electrode 10a is positioned over the gate oxide film 29a. This gate electrode 10a is a gate electrode for the depletion type lateral MOS field effect transistor in the p-well region 5. The gate electrode 10b is positioned over the gate oxide film 9b. This gate electrode 10b is a gate electrode for the enhancement type lateral MOS field effect transistor in the p-well region 5. The gate electrodes 10c are positioned over the gate oxide film 9c. This gate electrodes 10c are gate electrodes for the vertical MOS field effect transistors in the n⁻-type epitaxial layer 2.

With reference to FIG. 2G, a resist film is entirely applied over the gate electrodes 10a, 10b and 10c and the gate oxide films 9a, 9b and 9c as well as over the field oxide films 7a. The resist film is then patterned by a lithography technique to form a resist pattern 11 which covers the p-well region 5.

With reference to FIG. 2H, the resist pattern 11 and the gate electrodes 10c are used as masks for selective ion-implantation of boron as a p-type impurity into the n⁻-type epitaxial layer 2. The used resist pattern 11 is removed. A heat treatment is then carried out for activation of the implanted impurity at 1140° C. for a several tens minutes, thereby selectively forming p-type regions 12 in the n⁻-type epitaxial layer 2, wherein the p-type regions 12 are positioned under gaps between the gate electrodes 10c. The p-type regions 12 serve as body regions of the vertical MOS field effect transistors. Another resist film is further applied entirely over the gate electrodes 10a, 10b and 10c, and the gate oxide films 9a, 9b and 9c as well as over the field oxide films 7a. The resist film is then patterned by a lithography technique to form a resist pattern 13 which has openings positioned between the gate electrodes 10c and over the p-type regions 12, so that parts of the upper surfaces of the p-type regions 12 are exposed through the openings of the resist pattern 13.

With reference to FIG. 2I, the resist pattern 13 is used as a mask for selective ion-implantation of boron as a p-type impurity into the p-type regions 12 at a high impurity concentration. The resist pattern 13 is completely removed. A heat treatment is then carried out at 1000° C. for a several tends minutes for activation of the implanted impurity to selectively form p+-type regions 14 in the p-type regions 12. The p+-type regions 14 are higher in impurity concentration than the p-type regions 12. The p+type regions 14 serve to suppress effective operations of parasitic bipolar transistors to the vertical MOS field effect transistors. Still another resist film is entirely applied over the gate electrodes 10a, 10b and 10c, and the gate electrodes 9a, 9b and 9c as well as over the field oxide films 7a. The resist film is then patterned by a lithography technique to form resist patterns 15 which are positioned over the p+-type regions 14.

With reference to FIG. 2J, the resist patterns 15, the gate electrodes 10a, 10b and 10c and the field oxide films 7a are used as masks for selective ion-implantation of arsenic as an n-type impurity into selected regions in the p-well region 15 and in the p+-type regions 14 at a high impurity concentration. The used resist patterns 15 are completely removed. A heat treatment is then carried out at 1000° C. for several tends minutes for activation of the implanted impurity, thereby to selectively form n+-type regions 16a, 16b, 16c and 16d in the p-well region 5, and n+-type regions 16e in the p-type regions 12. The n+-type regions 16a and 16b serve as source and drain regions of the depletion type lateral MOS field effect transistor in the p-well region 5. The n+-type regions 16c and 16d serve as source and drain regions of the enhancement type lateral MOS field effect transistor in the p-well region 5. The n+-type regions 16e serve as source regions of the vertical MOS field effect transistors in the n⁻-type epitaxial layer 2. An inter-layer insulator 17 is entirely formed over the gate electrodes 10a, 10b and 10c, and the gate electrodes 9a, 9b and 9c as well as over the field oxide films 7a. Yet another resist film is entirely applied over the inter-layer insulator 17. The resist film is then patterned by a lithography technique to form a resist pattern 18 with openings which are positioned over contact regions of the inter-layer insulator 17.

With reference to FIG. 2K, the resist pattern 18 is used as a mask for selectively etching the inter-layer insulator 17 and the gate oxide films 9a, 9b and 9c to form contact holes in the inter-layer insulator 17. The contact holes are positioned over the n+-type regions 16a, 16b, 16c and 16d, as well as over the p+-type regions 14 and the n+-type regions 16e, whereby parts of the n+-type regions 16a, 16b, 16c and 16d as well as the p+-type regions 14 and parts of the n+-type regions 16e are exposed through the contact holes in the inter-layer insulator 17. The used resist pattern 18 is completely removed. An aluminum layer 19 is entirely formed over the inter-layer insulator 17 and within the contact holes, so that the aluminum layer 19 is in contact with the parts of the n+-type regions 16a, 16b, 16c and 16d as well as the p+-type regions 14 and the parts of the n+type regions 16e. A resist film is further applied entirely over the aluminum layer 19. The resist film is then patterned by a lithography technique to form a resist pattern 20.

With reference to FIG. 2L, the resist pattern 20 is used as a mask for selectively etching the aluminum layer 19 to form aluminum electrodes 19a, 19b, 19c, 19d, and 19e. The aluminum electrodes 19a and 19b are in contact with the source and drain regions 16a and 16b of the depletion type lateral MOS field effect transistor in the p-well region 5, so that the aluminum electrodes 19a and 19b serve as source and drain electrodes of the depletion type lateral MOS field effect transistor. The aluminum electrodes 19c and 19d are in contact with the source and drain regions 16c and 16d of the enhancement type lateral MOS field effect transistor in the p-well region 5, so that the aluminum electrodes 19c and 19d serve as source and drain electrodes of the enhancement type lateral MOS field effect transistor. The aluminum electrode 19c is in contact with the p+-type regions 14 and the parts of the n+-type regions 16e in the p-type regions 12, so that the aluminum electrode 19c serves as a source electrode of the vertical MOS field effect transistor. The used resist pattern 20 is completely removed. A bottom electrode 21 is formed on a bottom surface of the semiconductor substrate 1.

The above novel semiconductor device has a circuit configuration which includes the n-channel MOS field effect transistors and the p-channel MOS field effect transistors only. The above novel semiconductor device may be fabricated by small number of additional processes in additional to the processes for the vertical MOS field effect transistors. This allows a manufacturing cost reduction. The above novel semiconductor device is further advantageous in a reduced variation in threshold voltage of the depletion type lateral MOS field effect transistor. This makes it easy to design the circuit. If the variation in threshold voltage is suppressed within an acceptable range, then this means the semiconductor device to be non-defect, whereby a high yield can be obtained.

The following description will focus on the reason why the variation in the threshold voltage of the depletion type lateral MOS field effect transistor can be reduced by the above described novel method. Assuming that the enhancement type lateral MOS field effect transistor has a threshold voltage of about 1V and the depletion type lateral MOS field effect transistor has a threshold voltage of about −1V. At the same time when the field oxide films 7a are formed for suppressing the operation of the parasitic MOS field effect transistor, the additional oxide film 7b is also formed, which covers the upper surface of the n-type region 6. This additional oxide film 7b is formed by the oxidation of the upper region of the n-type region 6, whereby the interface of the n-type region 6 to the additional oxide film 7b lies at a lower level than an upper surface of the p-well region 5 or the upper surface of the original n-type region 6. In the oxidation process, a segregation and a shift of the interface of the n-type region 6 to the additional oxide film 7b in a downward direction reduce an effective depth of the p-n junction of the n-type region 6 to the p-well region 5 from the interface between the n-type region 6 and the additional oxide film 7b. Namely, the oxidation of the upper region of the original n-type region 6 for forming the additional oxide film 7b makes the p-n junction more shallow. The n-type region 6 includes a low concentration of boron as the p-type impurity and a high concentration of arsenic as the n-type impurity. The segregation in the oxidation of the upper region of the original n-type region 6 for forming the additional oxide film 7b reduces the concentration of boron as the p-type impurity in the n-type region 6. The reduced concentration of boron as the p-type impurity in the n-type region 6 suppresses the p-n junction from being deeper in a later heat treatment.

Thereafter, the additional oxide film 7b is removed. The gate oxide film 9a is formed over the n-type region 6, and then the gate electrode 10a is formed on the gate oxide film 9a. Since, as described above, the interface of the n-type region 6 to the additional oxide film 7b lies at a lower level than an upper surface of the p-well region 5, then the interface of the n-type region 6 to the gate oxide film 9a also lies at a lower level than an upper surface of the p-well region 5. This n-type region 6 serves as a channel region of the depletion type lateral MOS field effect transistor. Namely, the oxidation of the upper region of the original n-type region 6 for forming the additional oxide film 7b makes more shallow the p-n junction depth of the channel region of the depletion type lateral MOS field effect transistor.

The threshold voltage is almost proportional to a logarithm of the impurity concentration. For this reason, the variation in threshold voltage of the depletion type lateral MOS field effect transistor is much larger than the variation in threshold voltage of the enhancement type lateral MOS field effect transistor.

The p-n junction between the n-type region 6 and the p-well region 5 is so shallow that a depletion layer from the p-n junction reaches the gate oxide film 9a and no further extension of the depletion layer is possible, then a neutralization of charges at the p-n junction is established not only by the depletion layer but also injection of positive charges into the gate electrode 10a upon an additional voltage application to the gate electrode 10a. This additional voltage application to the gate electrode 10a increases the threshold voltage of the depletion type lateral MOS field effect transistor. If the threshold voltage of the depletion type lateral MOS field effect transistor is fixed, the decrease in depth of the p-n junction results in the increase in impurity concentration of the n-type region 6. The increase in impurity concentration of the n-type region 6 reduces the variation in threshold voltage of the depletion type lateral MOS field effect transistor. Namely, in order to reduce the variation in threshold voltage of the depletion type lateral MOS field effect transistor, it is effective to decrease the depth of the p-n junction between the n-type region 6 and the p-well region 5. In accordance with the above novel fabrication method, the p-n junction depth is so shallow as to make it easy to suppress variation in threshold voltage of the depletion type lateral MOS field effect transistor.

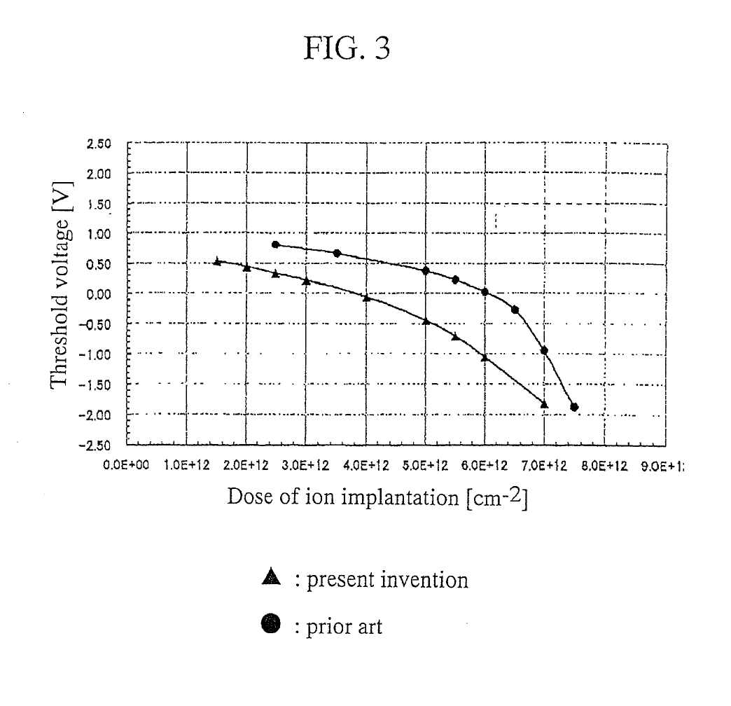

FIG. 3 is a diagram illustrative of variations in threshold voltage of the novel and conventional depletion type lateral MOS field effect transistors versus surface impurity concentration of channel region thereof in both the preferred embodiment of the present invention and the prior art. [ represents the variation in threshold voltage of the conventional depletion type lateral MOS field effect transistor versus surface impurity concentration of the channel region. ▴ represents the variation in threshold voltage of the novel depletion type lateral MOS field effect transistor versus surface impurity concentration of the channel region.

The novel depletion type lateral MOS field effect transistor is smaller than the conventional type lateral MOS field effect transistor in a gradient of the variation in threshold voltage versus surface impurity concentration of the channel region. The gradient depends on the variation of the threshold voltage. A large gradient means a large variation of the threshold voltage. A small gradient means a small variation of the threshold voltage. The gradient of the present invention is about one half of the gradient of the prior art. This means that the variation in threshold voltage among manufacturing lots of the present invention is reduced to about one half of that of the conventional one.

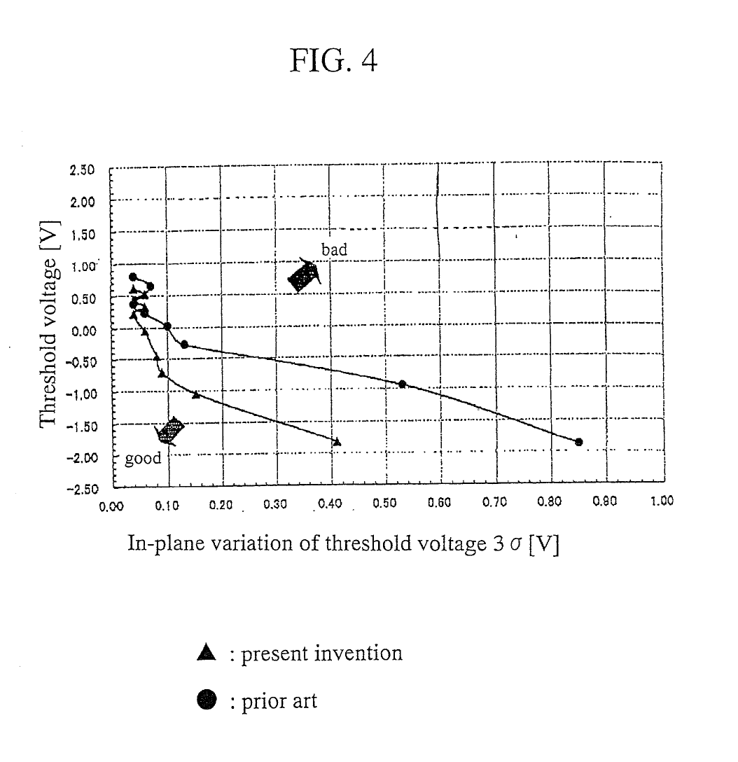

FIG. 4 is a diagram illustrative of threshold voltage values of the novel and conventional depletion type lateral MOS field effect transistors versus in-plane variations of the threshold voltage over wafer in both the preferred embodiment of the present invention and the prior art. ● represents the threshold voltage values of the conventional depletion type lateral MOS field effect transistor versus in-plane variations of the threshold voltage. ▴ represents the variation in threshold voltage of the novel depletion type lateral MOS field effect transistor versus in-plane variations of the threshold voltage.

If the threshold voltage is the same between the novel and conventional depletion type lateral MOS field effect transistors, the in-plane variations of the threshold voltage of the novel depletion type lateral MOS field effect transistor is about one half of the in-plane variations of the threshold voltage of the conventional depletion type lateral MOS field effect transistor. As the absolute value of the threshold voltage is large, the effect of reducing the in-plane variations of the threshold voltage is large.

FIG. 3 shows that the gradient of the variation in threshold voltage of the present invention is about one half of the gradient of the prior art. FIG. 4 shows that the in-plane variations of the threshold voltage of the present invention is about one half of the in-plane variations of the prior art. It may be supposed from the experimental data that the variation in the impurity concentration of the channel region of the depletion type lateral MOS field effect transistor is reduced into about one half of the conventional one.

In accordance with the above novel fabrication method, the ion-implantation of the p-type impurity and subsequent the ion-implantation of the n-type impurity are carried out before a single heat treatment for activating both the p-type and n-type impurities is carried out to form both the p-well region and the n-type channel region concurrently for the purpose of reducing the variation in the effective impurity concentration of the n-type channel region, wherein the effective impurity concentration is a subtraction of the p-type impurity concentration from the n-type impurity concentration. The reduction of the variation in the effective impurity concentration of the n-type channel region contributes to reduce the variation in threshold voltage of the depletion type lateral MOS field effect transistor even a variable amount of a heat by the heat treatment. Only about 10% or less of the total variation in the threshold voltage of the depletion type lateral MOS field effect transistor depends on the variation of the heat amount of the heat treatment. For this reason, the influence of the variation of the heat amount of the heat treatment to the variation in the threshold voltage of the depletion type lateral MOS field effect transistor is small.

It is possible as a modification that the vertical MOS field effect transistors have trench structures.

It is also possible as another modification that the vertical MOS field effect transistor is changed to an insulating gate bipolar transistor by changing the n+-type semiconductor substrate 1 to the p+-type semiconductor substrate.

Although the invention has been described above in connection with several preferred embodiments therefor, it will be appreciated that those embodiments have been provided solely for illustrating the invention, and not in a limiting sense. Numerous modifications and substitutions of equivalent materials and techniques will be readily apparent to those skilled in the art after reading the present application, and all such modifications and substitutions are expressly understood to fall within the true scope and spirit of the appended claims.

What is claimed is:

1. A channel region of a depletion type lateral field effect transistor, said channel region of a first conductivity type being selectively provided in a semiconductor region of a second conductivity type, and said channel region underlying a gate insulating film,
wherein an interface of said channel region to said gate insulating film lies at a lower level than an upper surface of said semiconductor region.

2. The channel region as claimed in claim 1, wherein said semiconductor region comprises a well region selectively provided in a semiconductor substrate.

3. The channel region as claimed in claim 1, wherein said channel region comprises a diffusion layer doped with an impurity of said first conductivity type which is for adjustment to a threshold voltage of said depletion type lateral field effect transistor.

4. A well region for a depletion type lateral field effect transistor, said well region of a second conductivity type being selectively provided in a semiconductor substrate, said well region having an upper surface and including an impurity diffused region which is selectively provided in said well region, and said impurity diffused region being doped with an impurity of a first conductivity type which is for adjustment to a threshold voltage of said depletion type lateral field effect transistor,
wherein said upper surface of said impurity diffused region lies at a lower level than said upper surface of said well region.

5. The well region as claimed in claim 1, wherein said upper surface of said impurity diffused region is bounded with a gate insulating film.

6. The well region as claimed in claim 1, wherein said impurity diffused region forms a channel layer of said depletion type lateral field effect transistor.

6. A semiconductor wafer comprising:
a semiconductor substrate of a first conductivity type;
an epitaxial layer of the first conductivity type overlying said semiconductor substrate;
a well region of a second conductivity type selectively provided in said epitaxial layer; and
an impurity diffused channel region being selectively provided in said well region, and said impurity diffused channel region being doped with an impurity of the first conductivity type which is for adjustment to a threshold voltage of a depletion type lateral field effect transistor,
wherein said upper surface of said impurity diffused channel region lies at a lower level than said upper surface of said well region.

7. The semiconductor wafer as claimed in claim 6, wherein said upper surface of said impurity diffused region is bounded with a gate insulating film.

8. A depletion type lateral MOS field effect transistor comprising:
a channel region of a first conductivity type being selectively provided in a semiconductor region of a second conductivity type;
source and drain regions of the first conductivity type being selectively provided in said semiconductor region, said channel region being interposed between said source and drain regions;
a gate insulating film extending over said channel region; and
a gate electrode provided on said gate insulating film,
wherein an interface of said channel region to said gate insulating film lies at a lower level than an upper surface of said semiconductor region.

9. The channel region as claimed in claim 8, wherein said semiconductor region comprises a well region selectively provided in an epitaxial layer of the first conductivity type, and said epitaxial layer overlying a semiconductor substrate of the first conductivity type.

10. The channel region as claimed in claim 8, wherein said channel region comprises a diffusion layer doped with an impurity of said first conductivity type which is for adjustment to a threshold voltage of said depletion type lateral field effect transistor.

11. A semiconductor wafer including:
an impurity diffused region of a first conductivity type being selectively provided in a semiconductor region of a second conductivity type; and
an oxide film overlying said impurity diffused region,
wherein an interface of said impurity diffused region to said oxide film lies at a lower level than an upper surface of said semiconductor wafer.

12. The semiconductor wafer as claimed in claim 11, wherein said semiconductor region comprises a well region selectively provided in a semiconductor substrate.

13. The semiconductor wafer as claimed in claim 11, wherein said channel region comprises a diffusion layer doped with an impurity of said first conductivity type which is for adjustment to a threshold voltage of a depletion type lateral field effect transistor.

14. The semiconductor wafer as claimed in claim 11, wherein said oxide film has a thickness of at least 5000 angstroms.

15. A method of forming a channel region of a depletion type lateral field effect transistor, comprising the steps of:
selectively forming a channel region of a first conductivity type in a semiconductor region of a second conductivity type;
subjecting an upper region of said channel region to a selective oxidation to form an oxide film which overlies said channel region,
wherein an interface of said impurity diffused region to said oxide film lies at a lower level than an upper surface of said semiconductor wafer.

16. The method as claimed in claim 15, wherein said oxide film has a thickness of at least 5000 angstroms.

17. The method as claimed in claim 15, wherein said semiconductor region comprises a well region selectively formed in an epitaxial layer over a semiconductor substrate.

18. The method as claimed in claim 15, wherein said channel region comprises a diffusion layer doped with an impurity of said first conductivity type which is for adjustment to a threshold voltage of a depletion type lateral field effect transistor.

19. The method as claimed in claim 15, wherein said oxidation is a wet oxidation.

20. The method as claimed in claim 15, wherein said oxide film overlying said channel region is formed at the same time of forming at least a field oxide film.

21. A method of forming a channel region of a depletion type lateral field effect transistor, comprising the steps of:
selectively introducing a first impurity of a second conductivity type at a first impurity concentration into a first selected region of a semiconductor region of a first conductivity type;
selectively introducing a second impurity of the first conductivity type at a second impurity concentration into a second selected region in said first selected region, said second impurity concentration being higher than said first impurity concentration;
carrying out a heat treatment for activating said first and second impurities to form a well region on said first selected region and a channel region on said second selected region concurrently; and
subjecting an upper region of said channel region to a selective oxidation to form an oxide film which overlies said channel region,
so that an interface of said impurity diffused region to said oxide film lies at a lower level than an upper surface of said semiconductor wafer.

22. The method as claimed in claim 21, wherein said oxide film has a thickness of at least 5000 angstroms.

23. The method as claimed in claim 21, wherein said semiconductor region comprises a well region selectively formed in an epitaxial layer over a semiconductor substrate.

24. The method as claimed in claim 21, wherein said channel region comprises a diffusion layer doped with an impurity of said first conductivity type which is for adjustment to a threshold voltage of a depletion type lateral field effect transistor.

25. The method as claimed in claim 21, wherein said oxidation is a wet oxidation.

26. The method as claimed in claim 21, wherein said oxide film overlying said channel region is formed at the same time of forming at least a field oxide film.
